(19) United States
(12) Patent Application Publication
(10) Pub. No.: US 2025/0113679 A1
(43) Pub. Date: Apr. 3, 2025

(54) LIGHT-EMITTING MODULE

(71) Applicant: FOSHAN NATIONSTAR OPTOELECTRONICS CO., LTD., Guangdong (CN)

(72) Inventors: Guanyu WANG, Foshan (CN); Zhenglong FAN, Foshan (CN); Hua ZHOU, Foshan (CN); Danwei LI, Foshan (CN); Mingwen LAN, Foshan (CN)

(21) Appl. No.: 18/774,266

(22) Filed: Jul. 16, 2024

(30) Foreign Application Priority Data
Sep. 28, 2023 (CN) 2023112782117
Sep. 28, 2023 (CN) 2023226622759

(51) Int. Cl. H01L 33/62; H01L 33/56

(52) U.S. Cl. CPC H10H 20/857; H10H 20/854

(57) ABSTRACT

A light-emitting module includes a lead frame, a substrate, a light-emitting element, a plastic encapsulation body, a driver IC chip and multiple passive devices. The substrate is disposed on the lead frame, and the light-emitting element, the driver IC chip and the multiple passive devices are disposed on the substrate. The substrate is a double-sided metal-plated insulated substrate. The plastic encapsulation body at least covers part of the lead frame, and a light condensation cavity is disposed in the plastic encapsulation body and covers above the light-emitting element. Circuit wires are further etched on the substrate, and the light-emitting element, the driver IC chip and the multiple passive devices are correspondingly connected based on the circuit wires.

### CROSS-REFERENCE TO RELATED APPLICATION(S)

This application claims the priority of a Chinese Patent Application No. 202311278211.7, filed on Sep. 28, 2023, and the priority of a Chinese Patent Application No. 202322662275.9, filed on Sep. 28, 2023, the disclosure of which are incorporated herein by reference in their entireties.

### TECHNICAL FIELD

The present disclosure relates to the technical field of light-emitting modules and in particular, to a light-emitting module.

### BACKGROUND

Under a current background of the increasingly widespread application of a high-power light-emitting module, the integrated packaging of light-emitting elements and driver IC chips is a development trend in the future. For existing high-power light-emitting module, to ensure the heat dissipation performance of the light-emitting module, a heat sink with a large volume needs to be disposed behind the light-emitting module, resulting in a relatively large overall volume of the light-emitting module, which is not conducive to the development towards the integrated packaging. In addition, in the integrated packaging of the light-emitting module, the light-emitting module is packaged with an opaque material in a fully wrapping manner and the opaque material is generally a plastic package material, which has a certain impact on the light-emitting performance of the light-emitting module.

Therefore, with the increasing degree of the integrated packaging of the light-emitting module, how to significantly reduce the volume of the light-emitting module, improve the heat dissipation performance of the light-emitting module and enhance the reliability of the light-emitting module without affecting optoelectronic parameters of the light-emitting module is a problem that needs to be solved urgently at present.

### SUMMARY

The present disclosure provides a light-emitting module. The light-emitting module includes a lead frame, a substrate, a light-emitting element, a plastic encapsulation body, a driver integrated circuit (IC) chip and multiple passive devices.

The substrate is disposed on the lead frame, and the light-emitting element, the driver IC chip and the multiple passive devices are disposed on the substrate.

The substrate is a double-sided metal-plated insulated substrate.

The plastic encapsulation body at least partially covers the lead frame, and a light condensation cavity is disposed in the plastic encapsulation body and covers above the light-emitting element.

One or more circuit wires are further etched on the substrate, and the light-emitting element, the driver IC chip and the multiple passive devices are correspondingly connected based on the circuit wires.

In some embodiments, the substrate is a double-sided copper-clad ceramic substrate.

In some embodiments, a nickel-plated gold layer is further disposed on the substrate.

In some embodiments, multiple grooves are disposed on the lead frame, and the substrate is placed on the lead frame where the multiple grooves are disposed.

In some embodiments, the multiple grooves are transverse stripe grooves, longitudinal stripe grooves or oblique stripe grooves and are parallel to each other, and the number is 2 or more.

In some embodiments, an optical light condensation component is disposed above the light condensation cavity.

In some embodiments, a fixing protection structure is disposed on at least one side surface of the light condensation cavity.

In some embodiments, the light condensation cavity includes a first circular truncated cone cavity and a second circular truncated cone cavity, where the first circular truncated cone cavity is disposed above the second circular truncated cone cavity.

In some embodiments, a diameter of an upper bottom surface of the first circular truncated cone cavity is greater than a diameter of a lower bottom surface of the first circular truncated cone cavity.

A diameter of an upper bottom surface of the second circular truncated cone cavity is greater than a diameter of a lower bottom surface of the second circular truncated cone cavity.

In some embodiments, a dam is disposed in the second circular truncated cone cavity, is disposed in an inner wall of the second circular truncated cone cavity and is located around the light-emitting element on the substrate.

In some embodiments, a cone angle of a circular truncated cone of the first circular truncated cone cavity is α, and a value range of α is 4° to 8°.

A cone angle of a circular truncated cone of the second circular truncated cone cavity is β, and a value range of β is 14° to 22°.

In some embodiments, the lead frame further includes multiple weld pins, where the multiple weld pins are in-line weld pins or surface mount weld pins.

In some embodiments, the light-emitting module further includes multiple bonding wires, where the substrate is correspondingly connected to the multiple weld pins based on the multiple bonding wires.

In some embodiments, a solder resist ink is disposed between pins of the light-emitting element, the driver IC chip and the multiple passive devices and the multiple bonding wires.

In some embodiments, the solder resist ink has a thickness ranging from 30 um to 40 um and a width ranging from 80 um to 120 um.

In some embodiments, multiple stress release holes are disposed on two edges of a front surface of the substrate.

In some embodiments, a waterproof groove is disposed on four edges of the front surface of the substrate.

In some embodiments, a stress release groove structure is disposed on a side surface of the substrate.

In some embodiments, multiple limit angles are further disposed on the lead frame and include at least two limit angles distributed at diagonal positions in four corners of the lead frame.

In some embodiments, any one of the multiple limit angles includes a transverse limit edge and a longitudinal limit edge, where a transverse limit edge and a longitudinal limit edge of the same limit angle in the multiple limit angles are disposed crosswise.

In some embodiments, any transverse limit edge includes a first limit structure and a second limit structure, where the first limit structure and the second limit structure are mountain-shaped.

Any longitudinal limit edge includes a third limit structure and a fourth limit structure, where the third limit structure and the fourth limit structure are mountain-shaped.

In some embodiments, an included angle between the first limit structure and the second limit structure of any transverse limit edge is 50° to 70°, and an included angle between the third limit structure and the fourth limit structure of any longitudinal limit edge is 50° to 70°.

In some embodiments, any transverse limit edge has the same structure, and any longitudinal limit edge has the same structure.

In some embodiments, the first limit structure of any transverse limit edge has a height ranging from 0.02 mm to 0.03 mm, and the second limit structure of any transverse limit edge has a height ranging from 0.05 mm to 0.1 mm.

The third limit structure of any longitudinal limit edge has a height ranging from 0.02 mm to 0.03 mm, and the fourth limit structure of any longitudinal limit edge has a height ranging from 0.05 mm to 0.1 mm.

In some embodiments, a material of the lead frame is a metal material.

In some embodiments, a positioning ink is further disposed on the substrate.

### BRIEF DESCRIPTION OF DRAWINGS

FIG. 1 is a first schematic diagram of a structure of a light-emitting module in some embodiments of the present disclosure.

FIG. 2 is a second schematic diagram of a structure of a light-emitting module in some embodiments of the present disclosure.

FIG. 3 is a third schematic diagram of a structure of a light-emitting module in some embodiments of the present disclosure.

FIG. 4 is a fourth schematic diagram of a structure of a light-emitting module in some embodiments of the present disclosure.

FIG. 5 is an enlarged view of a position a of FIG. 4.

FIG. 6 is a schematic diagram of a structure of a light condensation cavity in some embodiments of the present disclosure.

FIG. 7 is a schematic diagram of a structure of a solder resist ink in some embodiments of the present disclosure.

FIG. 8 is a schematic diagram a front surface of a structure of a substrate in some embodiments of the present disclosure.

FIG. 9 is a schematic diagram a front surface of a structure of a lead frame in some embodiments of the present disclosure.

FIG. 10 is a schematic diagram a side surface of a structure of a lead frame in some embodiments of the present disclosure.

FIG. 11 is a schematic diagram of a first transverse limit edge in some embodiments of the present disclosure.

FIG. 12 is a schematic diagram of a first longitudinal limit edge in some embodiments of the present disclosure.

FIG. 13 is a schematic diagram of a structure of a light-emitting module in some embodiments of the present disclosure.

### DETAILED DESCRIPTION

In the present disclosure, it is to be understood that terms such as “include” or “have” are intended to indicate the presence of features, numbers, steps, actions, components, portions or combinations thereof disclosed in this specification and are not intended to rule out the likelihood that one or more other features, numbers, steps, actions, components, portions or combinations thereof exist or are added.

In addition, it is to be noted that if not in collision, the embodiments and features therein in the present invention may be combined with each other. The present disclosure is described below in detail with reference to drawings and in conjunction with embodiments.

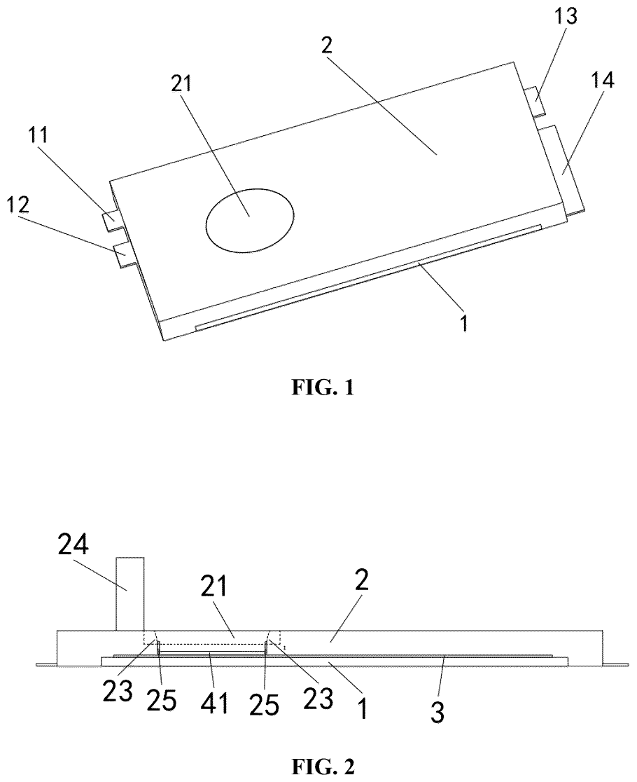

A light-emitting module involved in some embodiments of the present disclosure is shown in FIGS. 1 and 2. FIG. 1 is a first schematic diagram of a structure of a light-emitting module in an embodiment of the present disclosure, and FIG. 2 is a second schematic diagram of a structure of a light-emitting module in an embodiment of the present disclosure. FIG. 1 is a schematic diagram of a stereoscopic structure of the light-emitting module in some embodiments of the present disclosure. FIG. 2 is a side view of the light-emitting module in some embodiments of the present disclosure. The light-emitting module includes a lead frame 1, where multiple weld pins are disposed on the lead frame 1.

In an optional implementation manner of the present embodiments, the multiple weld pins include a first weld pin 11, a second weld pin 12, a third weld pin 13 and a fourth weld pin 14, where the first weld pin 11 and the second weld pin 12 are located on one side of the lead frame 1, and the third weld pin 13 and the fourth weld pin 14 are located on the other side of the lead frame 1.

In an optional implementation manner of the present embodiments, the first weld pin 11, the second weld pin 12, the third weld pin 13 and the fourth weld pin 14 are surface mount weld pins or may be in-line weld pins according to an actual design requirement.

In an optional implementation manner of the present embodiments, as shown in FIGS. 1 and 2, the light-emitting module further includes a plastic encapsulation body 2, where the plastic encapsulation body 2 covers the lead frame 1 and wraps part of the lead frame 1 in half-wrapping manner.

It is to be noted that the plastic encapsulation body 2 here may also have a structure fully wrapping the lead frame 1 and is also disposed according to an actual requirement.

Illustratively, according to an actual design requirement, if a bottom of the lead frame 1 does not need to be conductive, a half-wrapping structure may be used, no plastic encapsulation wrapping is performed on the bottom, and a heat sink may be added to the bottom to enhance heat dissipation; if the bottom of the lead frame 1 needs to be conductive, to avoid leakage of electricity, plastic encapsulation wrapping may also be performed on the bottom of the lead frame 1.

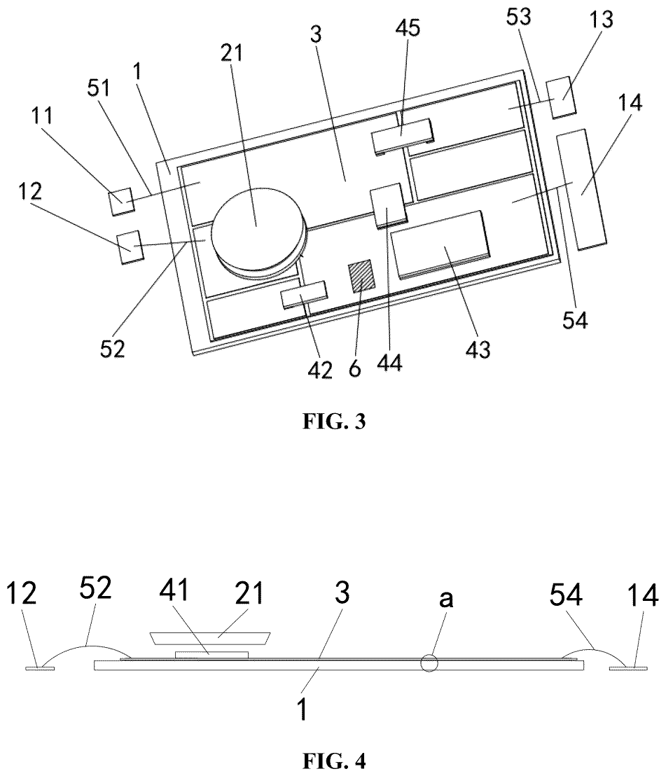

In an optional implementation manner of the present embodiments, as shown in FIGS. 3 and 4, FIG. 3 is a third schematic diagram of a structure of a light-emitting module in an embodiment of the present disclosure, and FIG. 4 is a fourth schematic diagram of a structure of a light-emitting module in an embodiment of the present disclosure. FIG. 3 is a schematic diagram of a stereoscopic structure of the light-emitting module in some embodiments of the present disclosure. FIG. 4 is a side view of the light-emitting module in some embodiments of the present disclosure.

It is to be noted that the plastic encapsulation body 2 is not shown in FIGS. 3 and 4 for better representing the structure of the light-emitting module in the embodiment of the present disclosure.

In an optional implementation manner of the present embodiments, as shown in FIGS. 3 and 4, the light-emitting module includes a substrate 3, where the substrate 3 is disposed on the lead frame 1.

In an optional implementation manner of the present embodiments, the substrate 3 is a double-sided metal-plated insulated substrate.

Illustratively, the substrate 3 is a double-sided copper-clad ceramic substrate.

Illustratively, the substrate 3 is a double-sided copper-clad ceramic substrate generated through a Direct Bonded Copper (DBC) process. That is, a copper foil is bonded on a surface of an insulated substrate, for example, a ceramic substrate, a eutectic liquid phase of copper/oxygen is formed at a high temperature under the intervention of an oxygen element and reacts with the ceramic substrate and the copper foil to generate copper aluminate or copper metaaluminate, the copper foil is bonded to the ceramic substrate under the action of a mesophase, and the double-sided copper-clad ceramic substrate is generated.

The substrate 3 is the double-sided copper-clad ceramic substrate with a simple manufacturing process, the adhesion strength between the copper foil and the ceramic substrate is enough, copper has superior conductivity performance and excellent metal ductility. Compared with a PCB board, a key point is that the bonding strength is large so that a void rate is reduced and copper is in direct contact with ceramic without an apparent intermediate layer so that an interface thermal resistance is reduced, a heat dissipation effect is strong and requirements of electrical insulation and high thermal conduction are implemented.

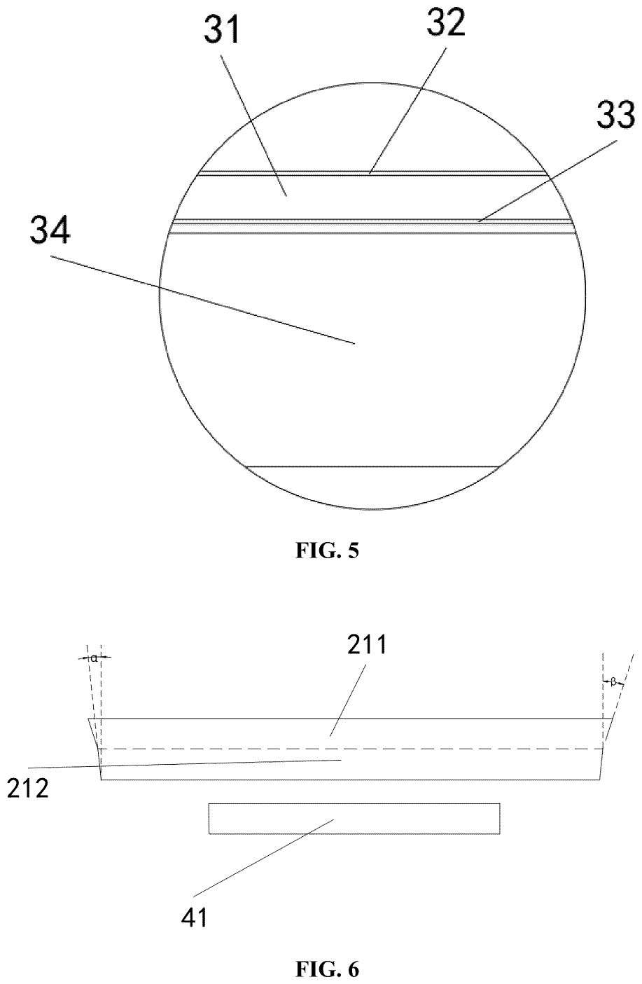

In an optional implementation manner of the present embodiments, as shown in FIG. 5, FIG. 5 is an enlarged view of a position a of FIG. 4. As shown in FIG. 5, the substrate 3 includes a ceramic layer 31, a top copper layer 32 and a bottom copper layer 33, where the top copper layer 32 is located on the ceramic layer 31, the bottom copper layer 33 is located under the ceramic layer 31, and the bottom copper layer 33 is welded on the lead frame 1 based on a solder.

In an optional implementation manner of the present embodiments, a light-emitting element 41, a driver integrated circuit (IC) chip 42 and multiple passive devices are disposed on the substrate 3. The multiple passive devices specifically include a first capacitor 43, a first resistor 44 and a second resistor 45, where the light-emitting element 41, the driver IC chip 42, the first capacitor 43, the first resistor 44 and the second resistor 45 are welded on the substrate 3 based on solders on respective pins.

In some embodiments, the light-emitting element 41 may be a light-emitting chip, a light-emitting device or a Zener diode.

In some embodiments, the light-emitting chip may be a blue-light chip, a green-light chip, a red-light chip, an ultraviolet chip and an infrared chip, the light-emitting device may be a single-color chip packaged device, for example, a blue chip packaged device with a fluorescent adhesive, or the light-emitting device may also be a multi-color packaged device, for example, an RGB chip packaged device with a transparent adhesive layer.

In an optional implementation manner of the present embodiments, one or more circuit wires are etched on the top copper layer 32 of the substrate 3, and the light-emitting element 41, the driver IC chip 42, the first capacitor 43, the first resistor 44 and the second resistor 45 are correspondingly connected by the circuit wires.

Illustratively, the circuit wires are etched on the top copper layer 32 of the substrate 3 in a chemical etching or laser etching manner.

In an optional implementation manner of the present embodiments, if the light-emitting element 41 and the driver IC chip 42 are flip chips, the light-emitting element 41 and the driver IC chip 42 are welded on the substrate 3 by solder on pins; if the light-emitting element 41 and the driver IC chip 42 are normal chips, the light-emitting element 41 and the driver IC chip 42 are welded on the substrate 3 in a wire bonding manner.

It is to be noted that if the light-emitting element 41 and the driver IC chip 42 are bare chips not subjected to die attachment packaging, the chips need to be fixed, and silver pastes are added to the pins to perform welding.

In an optional implementation manner of the present embodiments, multiple channels are further disposed on the substrate 3. The multiple channels are insulated channels formed through laser etching and have insulation and blocking functions.

Here, the substrate 3 is the double-sided copper-clad ceramic substrate, thereby significantly reducing a volume of the light-emitting module and enhancing the heat dissipation performance of the light-emitting module.

In an optional implementation manner of the present embodiments, a light condensation cavity 21 is disposed in the plastic encapsulation body 2, is located above the light-emitting element 41 and covers the light-emitting element 41, and an optical light condensation component is disposed on the upper part of the light condensation cavity 21 for focusing light.

Illustratively, a limit groove 23 is disposed on an outer side of the light condensation cavity 21, a fixing portion of the optical light condensation component is clamped in the limit groove 23 or adhered to the limit groove 23 by glue, and a light condensation portion of the optical light condensation component is located above the light condensation cavity 21 and covers the light condensation cavity 21.

In some embodiments, a fixing protection structure 24 is disposed on at least one side of the light condensation cavity 21 for limiting and fixing the optical light condensation component.

It is to be noted that the number of fixing protection structures 24 may be one, two, three, four or more and is determined according to an actual design requirement.

In an optional implementation manner of the present embodiments, the light condensation cavity 21 includes a first circular truncated cone cavity 211 and a second circular truncated cone cavity 212, where the first circular truncated cone cavity 211 is disposed above the second circular truncated cone cavity 212.

Illustratively, as shown in FIG. 6, FIG. 6 is a schematic diagram of a structure of a light condensation cavity 21 in an embodiment of the present disclosure. The light condensation cavity 21 is an inverted splayed circular truncated cone and includes the first circular truncated cone cavity 211 and the second circular truncated cone cavity 212. The first circular truncated cone cavity 211 is disposed above the second circular truncated cone cavity 212, and the optical light condensation component is disposed in the first circular truncated cone cavity 211.

Here, two inverted splayed circular truncated cone structures are superimposed to form a structure of the light condensation cavity 21, thereby achieving a better focusing effect of light emitted by a light-emitting device (LED).

It is to be noted that since FIG. 6 is a side view, the first circular truncated cone cavity 211 and the second circular truncated cone cavity 212 in FIG. 6 are displayed as isosceles trapezoids.

In an optional implementation manner of the present embodiments, a diameter of an upper bottom surface of the first circular truncated cone cavity 211 is greater than a diameter of a lower bottom surface of the first circular truncated cone cavity 211.

In an optional implementation manner of the present embodiments, a diameter of an upper bottom surface of the second circular truncated cone cavity 212 is greater than a diameter of a lower bottom surface of the second circular truncated cone cavity 212.

It is to be noted that the diameters of the upper bottom surfaces and the diameters of the lower bottom surfaces of the first circular truncated cone cavity 211 and the second circular truncated cone cavity 212 are adjusted according to a size of the light-emitting element 41.

Here, the diameter of the upper bottom surface of the first circular truncated cone cavity 211 is set to be greater than the diameter of the lower bottom surface of the first circular truncated cone cavity 211, the diameter of the upper bottom surface of the second circular truncated cone cavity 212 is set to be greater than the diameter of the lower bottom surface of the second circular truncated cone cavity 212, and the diameters of the upper bottom surfaces and the diameters of the lower bottom surfaces of the first circular truncated cone cavity 211 and the second circular truncated cone cavity 212 are adjusted according to the size of the light-emitting element 41 so that in a manufacturing process, after plastic encapsulation is performed to form the light condensation cavity 21, a demolding effect of a mold is better, and the efficiency is higher, thereby improving the production efficiency of the light-emitting module.

In an optional implementation manner of the present embodiments, a dam 25 is disposed in the second circular truncated cone cavity 212.

Illustratively, the dam 25 is disposed in an inner wall of the second circular truncated cone cavity 212 and is located around the light-emitting element 41 on the substrate 3.

It is to be noted that since the light condensation cavity 21 is formed above the light-emitting element 41, when the light-emitting element 41 is the light-emitting chip, an encapsulation layer needs to be formed in a dispensing manner to perform encapsulation protection on the light-emitting chip. Moreover, when the light-emitting chip is the blue-light chip, a phosphor may be added to the encapsulation layer to emit white light. In a dispensing process, dispensing is performed in a U-shape, and a colloid climbs up along two sides of the light condensation cavity 21. Here, the dam 25 is disposed for preventing the colloid from climbing up in the dispensing process, thereby improving light emission quality.

In some embodiments, the dam 25 may also be used for reducing a range of a light-emitting angle of the light-emitting element 41 so that a light-emitting area is not changed and brightness is enhanced.

More, the dam 25 may also flexibly control a dispensing amount according to a light emission requirement of the light-emitting module. An upper surface of the encapsulation layer formed through the dispensing is controlled to be flat, concave or convex, thereby achieving an effect of normal light emission, light condensation or diffusion.

More, when the light-emitting element 41 is the blue-light chip, if the dam 25 is disposed, a fluorescent film may be pasted instead of a process of dispensing a fluorescent adhesive to form the encapsulation layer. The dam 25 is used for fixing the fluorescent film, thereby implementing an object of changing a light emission color of the light-emitting chip.

It is to be noted that to not affect light-emitting quality, a height of the dam 25 is flush with a light-emitting surface at the top of the light-emitting element 41.

In an optional implementation manner of the present embodiments, a material of the dam 25 may be a white silica gel, thereby enhancing reflective intensity of light emitted by the light-emitting chip and reducing optical loss.

In an optional implementation manner of the present embodiments, a shape of the dam 25 may be multiple shapes such as a square, a circle or an ellipse and is determined according to an actual design requirement.

In an optional implementation manner of the present embodiments, a cone angle of a circular truncated cone of the first circular truncated cone cavity 211 is α, and a value range of α is 4° to 8°.

Illustratively, a value of α is 6°.

In an optional implementation manner of the present embodiments, a cone angle of a circular truncated cone of the second circular truncated cone cavity 212 is β, and a value range of β is 14° to 22°.

Illustratively, a value of β is 18°.

It is to be noted that since the values of a and B are set here in a manufacturing process of the light-emitting module, a demolding process is more convenient in a manufacturing process of the light condensation cavity 21.

Here, the light condensation cavity 21 is disposed, and a size of the light condensation cavity 21 is designed, thereby focusing light emitted by the light-emitting element 41 with relatively large efficiency and effectively improving the light-emitting performance of the light-emitting module.

Here, the light condensation cavity 21 is disposed, and the optical light condensation component is disposed in a light condensation hole of the light condensation cavity 21 for focusing light, thereby ensuring the light-emitting performance of the light-emitting module.

In an optional implementation manner of the present embodiments, a nickel-plated gold layer is further disposed on the substrate 3 and covers the top copper layer 32 and the bottom copper layer 33 of the substrate 3.

Illustratively, the light condensation cavity 21 is disposed in the plastic encapsulation body 2 and the optical light condensation component is disposed to focus light, which will affect solder pastes or silver pastes at the pins of the light-emitting element 41, the driver IC chip 42 and other passive devices. Here, the nickel-plated gold layer is disposed with an extremely thin overall thickness and plays a role in anti-oxidation without affecting welding quality, thereby effectively protecting the light-emitting module and improving the reliability of the light-emitting module.

In an optional implementation manner of the present embodiments, the light-emitting module further includes multiple bonding wires, where the substrate 3 is correspondingly connected to the multiple weld pins based on the multiple bonding wires.

Illustratively, as shown in FIGS. 3 and 4, a first bonding wire 51, a second bonding wire 52, a third bonding wire 53 and a fourth bonding wire 54 are disposed in the light-emitting module. The first bonding wire 51 is used for connecting the substrate 3 to the first weld pin 11, the second bonding wire 52 is used for connecting the substrate 3 to the second weld pin 12, the third bonding wire 53 is used for connecting the substrate 3 to the third weld pin 13, and the fourth bonding wire 54 is used for connecting the substrate 3 to the fourth weld pin 14.

In an optional implementation manner of the present embodiments, the multiple bonding wires are aluminum wires, gold wires or silver wires.

In an optional implementation manner of the present embodiments, a positioning ink 6 is further disposed on the substrate 3 and is disposed beside the driver IC chip 42.

In conclusion, some embodiments of the present disclosure provide the light-emitting module. The double-sided copper-clad ceramic substrate is prepared by using the Direct Bonded Copper process, thereby significantly reducing the volume of the light-emitting module and enhancing the heat dissipation performance of the light-emitting module. The light condensation cavity 21 is disposed in the plastic encapsulation body 2, and the optical light condensation component is disposed to focus the light emitted by the light-emitting element 41, thereby ensuring the light-emitting performance of the light-emitting module. The nickel-plated gold layer is disposed on the substrate 3, thereby effectively preventing the corrosion problem caused by an effect on a sealing property after the light condensation cavity 21 is disposed in the plastic encapsulation body 2 and improving the reliability of the light-emitting module. The fixing protection structure 24 is disposed on at least one side surface of the light condensation cavity 21 to fix and protect the optical light condensation component, thereby improving the reliability of the light-emitting module. The dam 25 is disposed in the second circular truncated cone cavity 212, is disposed in the inner wall of the second circular truncated cone cavity 212 and is located around the light-emitting element 41 on the substrate 3, thereby effectively preventing an overflow of glue during the dispensing, improving the light-emitting performance of the light-emitting module and improving the reliability of the light-emitting module. The bonding wires are the aluminum wires, the gold wires or the silver wires, thereby ensuring that the substrate 3 is stably connected to the weld pins. The overall structure can implement an integrated packaging structure.

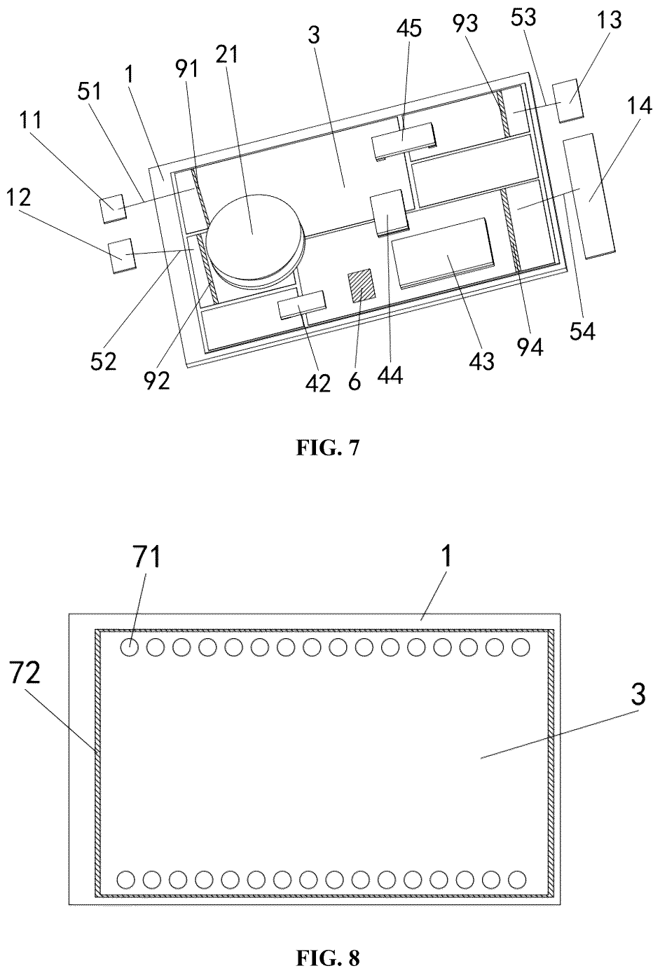

A light-emitting module is involved in some embodiments of the present disclosure and is basically the same as the light-emitting module in preceding embodiments. The light-emitting module in the present embodiments differs from the light-emitting module in preceding embodiments mainly in that as shown in FIG. 7, in an optional implementation manner of the present embodiments, one or more solder resist inks 9 are disposed among the pins of the light-emitting element 41, the driver IC chip 42 and the multiple passive devices and the multiple bonding wires.

Illustratively, as shown in FIG. 7, FIG. 7 is a schematic diagram of a structure of solder resist inks 9 in an embodiment of the present disclosure. The light-emitting module includes a first solder resist ink 91, a second solder resist ink 92, a third solder resist ink 93 and a fourth solder resist ink 94, where the first solder resist ink 91 is used for blocking the first bonding wire 51, the second solder resist ink 92 is used for blocking the second bonding wire 52, the third solder resist ink 93 is used for blocking the third bonding wire 53, and the fourth solder resist ink 94 is used for blocking the fourth bonding wire 54.

In an optional implementation manner of the present embodiments, any one of the solder resist inks 9 has a thickness ranging from 30 um to 40 um, for example 35 um, and has a width ranging from 80 um to 120 um, for example 100 um.

It is to be noted that since the double-sided copper-clad ceramic substrate prepared through the DBC process is used in the light-emitting module in the present embodiments, when the light-emitting element 41, the driver IC chip 42 and other passive devices are welded, the solder pastes are generally used for the welding. In the welding process, the solder creeps along a surface of the top copper layer 32 of the substrate 3, thereby affecting the overall electrical connection of the light-emitting module. Moreover, since a distance between the substrate 3 and the weld pin on the lead frame 1 is relatively long, a length of the bonding wire between the substrate 3 and the weld pin is relatively long, and wire diameters of a conventional gold wire and a silver wire are relatively small, undesirable phenomena such as breakage and wire collapse easily occurs during long-distance bonding, thereby affecting the reliability of the light-emitting module with a relatively high cost. Therefore, in the large-size light-emitting module in the present embodiments, an aluminum wire with a large wire diameter, high reliability and a low cost is used for bonding.

However, since the wire diameter of the aluminum wire is relatively large, a requirement for a welding area is relatively large while performing ultrasonic welding. If the solder creeping occurs, an insufficient welding area is easily caused, and if the solder creeping is in contact with the aluminum wire, a short circuit easily occurs. Here, the solder resist ink 9 is disposed, thereby blocking the solder creeping, preventing the short circuit during the welding and playing a role in positioning and preventing the component from shifting a position. The thickness of the solder resist ink 9 is for example 35 um. If the thickness is relatively large, the solder resist ink 9 is easy to peel off. Moreover, the overall thickness of the light-emitting module is not affected. The width of the solder resist ink 9 is for example 100 um so that an occupied area is relatively small and the overall area of the light-emitting module is not affected, thereby contributing to the development towards a miniaturization trend.

In conclusion, some embodiments of the present disclosure provide the light-emitting module. The solder resist inks 9 are disposed on the substrate 3 so that the solder creeping is prevented during the welding, which affects the electrical connection between the substrate 3 and the weld pins. The overall structure can implement the integrated packaging structure.

A light-emitting module is involved in some embodiments of the present disclosure and is basically the same as the light-emitting module in preceding embodiments. The light-emitting module in the present embodiments differs from the light-emitting module in preceding embodiments mainly in that in an optional implementation manner of the present embodiments, multiple stress release holes 71 are longitudinally arranged on two edges of a front surface of the substrate 3.

In an optional implementation manner of the present embodiments, as shown in FIG. 8, FIG. 8 is a schematic diagram of a structure of a front surface of a substrate 3 in an embodiment of the present disclosure.

It is to be noted that since the double-sided copper-clad ceramic substrate used in the light-emitting module in the present embodiments has a relatively large size, for example, a 6 mm*10 mm or even a larger-sized substrate 3, certain problems may occur in the stress reliability of the substrate 3 and a bonding force between the substrate 3 and the plastic encapsulation body 2. Here, the multiple stress release holes 71 are disposed, thereby improving the bonding strength between the surrounding plastic encapsulation body 2 and the substrate 3, reducing a stress change of the substrate 3 and improving the reliability of the light-emitting module.

In an optional implementation mode of the present embodiments, a waterproof groove 72 is disposed on four edges of the front surface of the substrate 3.

It is to be noted that the waterproof groove 72 is disposed here, thereby improving the bonding strength between the plastic encapsulation body 2 and the substrate 3, playing a role in preventing water vapor and moisture and improving the reliability of the light-emitting module.

In an optional implementation manner of the present embodiments, a stress release groove structure is disposed on a side surface of the substrate 3.

Illustratively, the stress release groove structure may be a threaded structure, a zigzag structure or a wave-shaped structure and is disposed according to an actual design requirement.

It is to be noted that the stress release groove structure is disposed on the side surface of the substrate 3, thereby also improving the bonding strength between the plastic encapsulation body 2 and the substrate 3, reducing the stress change and improving the reliability of the light-emitting module.

In conclusion, some embodiments of the present disclosure provide the light-emitting module. The stress release holes 71 are disposed on two edges of the front surface of the substrate 3, respectively, the waterproof groove 72 is disposed on four edges of the front surface of the substrate 3, and the stress release groove structure is disposed on the side surface of the substrate 3, thereby effectively improving the bonding strength between the plastic encapsulation body 2 and the lead frame 1 and the substrate 3, reducing the stress change, enhancing the moisture-proof performance of the light-emitting module and improving the reliability. The overall structure can implement the integrated packaging structure.

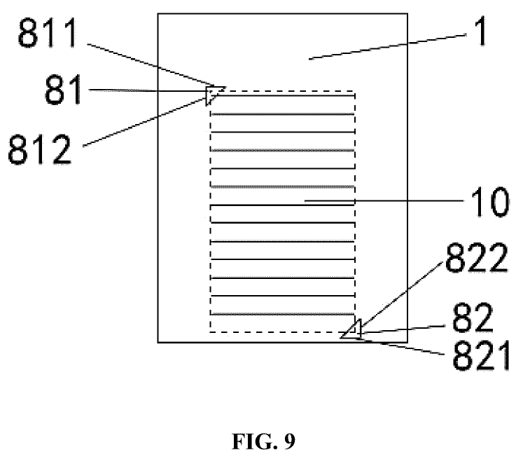

A light-emitting module is involved in some embodiments of the present disclosure and is basically the same as the light-emitting module in preceding embodiments. The light-emitting module in the present embodiments differs from the light-emitting module in preceding embodiments mainly in that as shown in FIG. 9, FIG. 9 is a schematic diagram of a structure of a lead frame 1 in an embodiment of the present disclosure, multiple grooves are disposed on the lead frame 1, and the substrate 3 covers the multiple grooves. In an optional implementation manner of the present embodiments, a material of the lead frame 1 is a metal material.

Illustratively, the material of the lead frame 1 is copper.

Here, the material of the lead frame 1 is selected as copper, which has good metal ductility and thermal conductivity, thereby effectively improving the heat dissipation performance.

In an optional implementation manner of the present embodiments, a die bonding region 10 is disposed on the lead frame 1, and the multiple grooves are disposed in the die bonding region 10.

Illustratively, as shown in FIG. 9, a dotted line box in FIG. 9 is the die bonding region 10.

Illustratively, the multiple grooves are transverse stripe grooves, longitudinal stripe grooves or oblique stripe grooves and are parallel to each other, and the number of the multiple grooves is 2 or more, for example, the number of multiple grooves may be two, three, five or ten. FIG. 9 illustrates the case where the transverse stripe grooves are disposed.

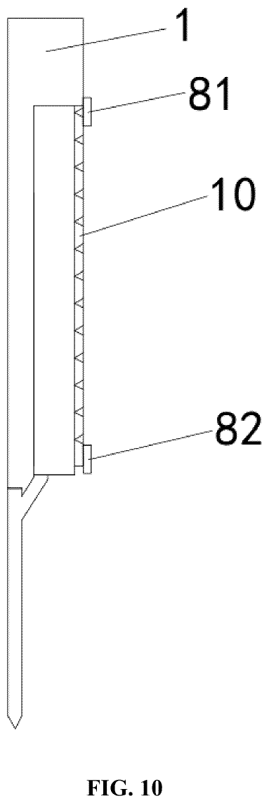

In an optional implementation manner of the present embodiments, the multiple grooves may be triangular grooves, or may be semi-circular grooves, rectangular grooves or semi-elliptical grooves. What are shown in FIG. 10 are the triangular grooves.

In an optional implementation manner of the present embodiments, the multiple grooves are formed in manners such as punching by a punching tool, chemical etching or laser etching.

Here, the multiple grooves are disposed, thereby implementing a solder exhaust function and effectively reducing the void rate.

In an optional implementation manner of the present embodiments, the die bonding region 10 has a rectangular structure, a triangular structure or another polygonal structure. Multiple limit angles are further disposed on the lead frame 1 and include at least two limit angles distributed at diagonal positions in four corners of the lead frame 1.

Illustratively, FIG. 9 illustrates the case where two limit angles are disposed. Illustratively, a first limit angle 81 and a second limit angle 82 are disposed in the die bonding region 10. The first limit angle 81 is disposed in an upper left corner of the die bonding region 10, and the second limit angle 82 is disposed in a lower right corner of the die bonding region 10.

It is to be noted that the number of limit angles is at least two and the at least two limit angles are disposed at diagonal positions, that is, the upper left corner and the lower right corner or the lower left corner and the upper right corner. The number and the positions of the limit angles are set according to an actual situation, that is, the number of limit angles may be three, four or more, and the positions may be separately disposed in any one of the four corners of the lead frame 1 and any position on any one of the four sides of the lead frame 1.

Here, the grooves are disposed so that the heat dissipation performance of the light-emitting module is improved, and the limit angles are disposed so that the substrate 3 can be limited and fixed in cooperation with solder to prevent a deviation of a position of the substrate 3.

More, if the limit angles are disposed on four sides of the die bonding region 10, a limit angle of the limit angles located on a transverse side is set to be a transverse limit edge, and another limit angle of the limit angles located on a longitudinal side is set to be a longitudinal limit edge.

In an optional implementation manner of the present embodiments, any one of the limit angles includes a transverse limit edge and a longitudinal limit edge, where a transverse limit edge and a longitudinal limit edge of the same limit angle are disposed crosswise.

Illustratively, the first limit angle 81 includes a first transverse limit edge 811 and a first longitudinal limit edge 812, and the second limit angle 82 includes a second transverse limit edge 821 and a second longitudinal limit edge 822, where the first transverse limit edge 811 and the first longitudinal limit edge 812 are disposed crosswise, and the second transverse limit edge 821 and the second longitudinal limit edge 822 are disposed crosswise.

It is to be noted that an included angle formed between the transverse limit edge and the longitudinal limit edge of the same limit angle may be an acute angle, a right angle or an obtuse angle. Illustratively, the formed included angle is 60° to 90°.

Here, illustratively, the included angle formed between the transverse limit edge and the longitudinal limit edge of the same limit angle is 60° to 90° so that a limit fixing effect of the limit angle can be more stable.

In an optional implementation manner of the present embodiments, any transverse limit edge includes a first limit structure 8111 and a second limit structure 8112, and any longitudinal limit edge includes a third limit structure 8121 and a fourth limit structure 8122.

In an optional implementation manner of the present embodiments, as shown in FIG. 11, FIG. 11 is a schematic diagram of a first transverse limit edge 811 in some embodiments of the present disclosure. The first transverse limit edge 811 includes the first limit structure 8111 and the second limit structure 8112, where the first limit structure 8111 and the second limit structure 8112 are mountain-shaped, and a height of the second limit structure 8112 is higher than that of the first limit structure 8111.

In an optional implementation manner of the present embodiments, a height of the first limit structure 8111 of any transverse limit edge ranges from 0.02 mm to 0.03 mm, and a height of the second limit structure 8112 of any transverse limit edge ranges from 0.05 mm to 0.1 mm.

Illustratively, as shown in FIG. 11, a height between the highest point of the first limit structure 8111 and the lead frame 1 is h1 with a value range of 0.02 mm to 0.03 mm, and a height between the highest point of the second limit structure 8112 and the lead frame 1 is h2 with a value range of 0.05 mm to 0.1 mm.

Here, the heights of the first limit structure 8111 and the second limit structure 8112 are set, thereby ensuring the limit fixing effect of the substrate 3 and effectively improving the reliability.

In an optional implementation manner of the present embodiments, an included angle between the first limit structure 8111 and the second limit structure 8112 ranges from 50° to 70°.

Illustratively, as shown in FIG. 11, the included angle between the first limit structure 8111 and the second limit structure 8112 is α1, and a value range of 1 is 50° to 70°.

Illustratively, the included angle between the first limit structure 8111 and the second limit structure 8112 is 60°, that is, an angle of α1 is 60°.

Here, the included angle between the first limit structure 8111 and the second limit structure 8112 is selected as 60° so that the first limit structure 8111 and the second limit structure 8112 are more stable and can firmly limit and fix the substrate 3.

In an optional implementation manner of the present embodiments, an angle between a side of the second limit structure 8112 facing the die bonding region 10 and a horizontal plane ranges from 90° to 120°.

Illustratively, as shown in FIG. 11, the angle between the side of the second limit structure 8112 facing the die bonding region 10 and the horizontal plane is α2, and a value range of α2 is 90° to 120°.

Here, the angle between the side of the second limit structure 8112 facing the die bonding region 10 and the horizontal plane is set to be 90° to 120° so that the insertion and removal of the substrate 3 are not affected while the second limit structure 8112 limits and fixes the substrate 3.

In an optional implementation manner of the present embodiments, the first limit structure 8111 and the second limit structure 8112 are formed through stamping.

Illustratively, the lead frame 1 is made of a metal, for example, copper, which has good metal ductility. Here, a stamping tool is used for pressing downward at about 60° to the horizontal plane in a direction of arrow in FIG. 11. Since the metal copper has excellent metal ductility, two mountain-shaped limit structures are formed, one of which is high, and the other of which is low.

The relatively low limit structure is the first limit structure 8111, and the relatively high limit structure is the second limit structure 8112. The second limit structure 8112 is in contact with the substrate 3 and fixes and limits the substrate 3.

It is to be noted that any transverse limit edge has the same structure, that is, a structure of the second transverse limit edge 821 is the same as a structure of the first transverse limit edge 811, which is not repeated here.

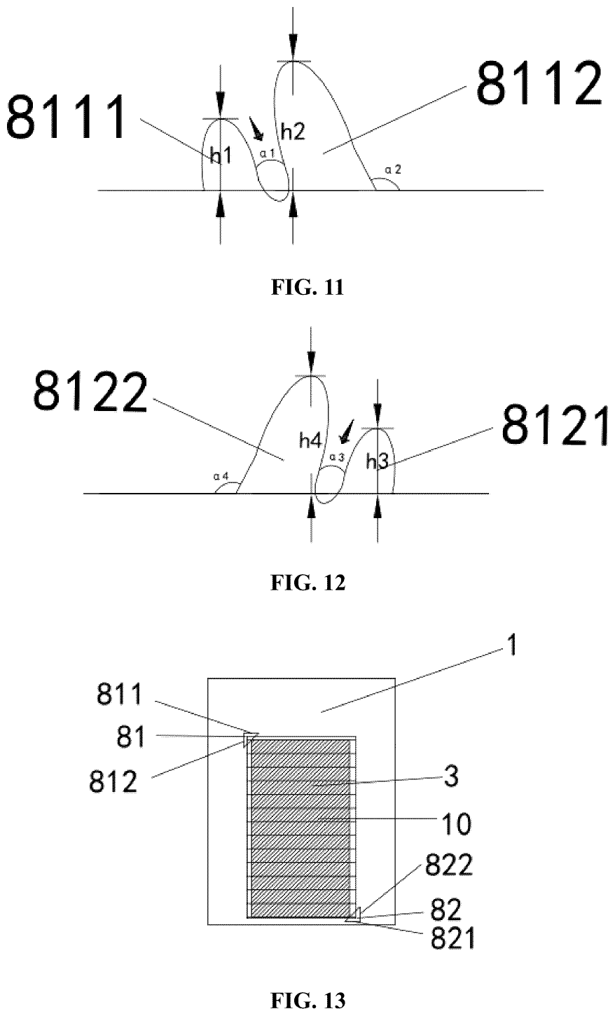

In an optional implementation manner of the present embodiments, as shown in FIG. 12, FIG. 12 is a schematic diagram of a first longitudinal limit edge 812 in some embodiments of the present disclosure. The first longitudinal limit edge 812 includes the third limit structure 8121 and the fourth limit structure 8122, where the third limit structure 8121 and the fourth limit structure 8122 are mountain-shaped, and a height of the fourth limit structure 8122 is higher than that of the third limit structure 8121.

In an optional implementation manner of the present embodiments, a height of the third limit structure 8121 of any longitudinal limit edge ranges from 0.02 mm to 0.03 mm, and a height of the fourth limit structure 8122 of any longitudinal limit edge ranges from 0.05 mm to 0.1 mm.

Illustratively, as shown in FIG. 12, a height between the highest point of the third limit structure 8121 and the lead frame 1 is h3 with a value range of 0.02 mm to 0.03 mm, and a height between the highest point of the fourth limit structure 8122 and the lead frame 1 is h4 with a value range of 0.05 mm to 0.1 mm.

Here, the heights of the third limit structure 8121 and the fourth limit structure 8122 are set, thereby ensuring the limit fixing effect of the substrate 3 and effectively improving the reliability.

In an optional implementation manner of the present embodiments, an included angle between the third limit structure 8121 and the fourth limit structure 8122 ranges from 50° to 70°.

Illustratively, as shown in FIG. 12, the included angle between the third limit structure 8121 and the fourth limit structure 8122 is α3, and a value range of α3 is 50° to 70°.

Illustratively, the included angle between the third limit structure 8121 and the fourth limit structure 8122 is 60°, that is, an angle of α3 is 60°.

Here, the included angle between the third limit structure 8121 and the fourth limit structure 8122 is selected as 60° so that the third limit structure 8121 and the fourth limit structure 8122 are more stable and can firmly limit and fix the substrate 3.

In an optional implementation manner of the present embodiments, an angle between a side of the fourth limit structure 8122 facing the die bonding region 10 and the horizontal plane ranges from 90° to 120°.

Illustratively, as shown in FIG. 12, the angle between the side of the fourth limit structure 8122 facing the die bonding region 10 and the horizontal plane is α4, and a value range of α4 is 90° to 120°.

Here, the angle between the side of the fourth limit structure 8122 facing the die bonding region 10 and the horizontal plane is set to be 90° to 120° so that the insertion and removal of the substrate 3 are not affected while the fourth limit structure 8122 limits and fixes the substrate 3.

In an optional implementation manner of the present embodiments, the third limit structure 8121 and the fourth limit structure 8122 are formed through stamping.

Illustratively, the lead frame 1 is made of the metal, for example, copper, which has good metal ductility. Here, the stamping tool is used for pressing downward at about 60° to the horizontal plane in a direction of arrow in FIG. 12. Since the metal copper has excellent metal ductility, two mountain-shaped limit structures are formed, one of which is high, and the other of which is low. The relatively low limit structure is the third limit structure 8121, and the relatively high limit structure is the fourth limit structure 8122. The fourth limit structure 8122 is in contact with the substrate 3 and fixes and limits the substrate 3.

It is to be noted that any longitudinal limit edge has the same structure, that is, a structure of the second longitudinal limit edge 822 is the same as a structure of the first longitudinal limit edge 812, which is not repeated here.

Here, the first limit angle 81 and the second limit angle 82 are disposed to fix and limit the substrate 3 so that in the case where the volatilization of a flux in the solder is not affected, the substrate 3 is fixed to prevent from deviation, thereby ensuring the heat dissipation performance of a product, effectively reducing the void rate and improving the quality of the product.

In conclusion, the die bonding region 10 is disposed on the lead frame 1, and the multiple parallel grooves are disposed in the die bonding region 10, thereby implementing the solder exhaust function. Moreover, the limit angles are disposed in the die bonding region 10 to fix and limit the substrate 3 so that in the case where the volatilization of the flux in the solder is not affected, the substrate 3 is fixed to prevent from the deviation, thereby ensuring the heat dissipation performance of the product, effectively reducing the void rate and improving the quality of the product.

In an optional implementation manner of the present embodiments, the positioning ink 6 is further disposed on the substrate 3 and is disposed beside the driver IC chip 42.

In conclusion, some embodiments of the present disclosure provide the light-emitting module. The limit angles are disposed for limiting and fixing the substrate 3, and accurate positioning is performed in combination with the positioning ink 6, thereby preventing the substrate 3 from the deviation. The overall structure can implement the integrated packaging structure.

Some embodiments of the present disclosure provide a light-emitting module. The light-emitting module includes the lead frame 1, the substrate 3 and the multiple components in some embodiments, where the multiple components are welded on the substrate 3, the substrate 3 is welded in the die bonding region 10 of the lead frame 1, and the limit angles limit and fix the substrate 3.

In an optional implementation manner of the present embodiments, as shown in FIG. 13, FIG. 13 is a schematic diagram of a structure of a light-emitting module in some embodiments of the present disclosure. The light-emitting module includes the lead frame 1, where the die bonding region 10 is disposed on the lead frame 1, the multiple parallel grooves are disposed in the die bonding region 10, the substrate 3 (a shadow formed by oblique lines in FIG. 13) is disposed above the multiple parallel grooves in the die bonding region 10 of the lead frame 1, and the multiple components are disposed on the substrate 3. The limit angles are disposed on the lead frame 1 and include the first limit angle 81 located in the upper left corner of the die bonding region 10 and the second limit angle 82 located in the lower right corner of the die bonding region 10, where the first limit angle 81 and the second limit angle 82 cooperate with each other to limit and fix the substrate 3 in the die bonding region 10 of the lead frame 1.

In an optional implementation manner of the present embodiments, the first limit angle 81 includes the first transverse limit edge 811 and the first longitudinal limit edge 812, and the second limit angle 82 includes the second transverse limit edge 821 and the second longitudinal limit edge 822, where the first transverse limit edge 811 and the first longitudinal limit edge 812 are disposed crosswise, and the second transverse limit edge 821 and the second longitudinal limit edge 822 are disposed crosswise.

In conclusion, some embodiments of the present disclosure provide the light-emitting module. The limit angles are disposed for limiting and fixing the substrate 3, and the accurate positioning is performed in combination with the positioning ink 6, thereby preventing the substrate 3 from the deviation. The overall structure can implement the integrated packaging structure.

In the present disclosure, the double-sided copper-clad ceramic substrate using a Direct Bonded Copper process is used, and the grooves are disposed in the lead frame, thereby significantly reducing the volume of the light-emitting module and enhancing the heat dissipation performance of the light-emitting module; the light condensation cavity is disposed in the plastic encapsulation body, and the optical light condensation component is disposed to focus the light emitted by the light-emitting element, thereby ensuring the light-emitting performance of the light-emitting module; the nickel-plated gold layer is disposed on the substrate, thereby effectively preventing the corrosion problem caused by an effect on a sealing property after the light condensation cavity is disposed in the plastic encapsulation body and improving the reliability of the light-emitting module; the fixing protection structure is disposed on the at least one side surface of the light condensation cavity to fix and protect the optical light condensation component, thereby improving the reliability of the light-emitting module; the dam is disposed in the second circular truncated cone cavity, is disposed in the inner wall of the second circular truncated cone cavity and is located around the light-emitting element on the substrate, thereby effectively preventing an overflow of glue during dispensing, improving the light-emitting performance of the light-emitting module and improving the reliability of the light-emitting module; the solder resist ink is disposed on the substrate so that solder creeping is prevented during welding, which affects the electrical connection between the substrate and the weld pins; the holes are disposed on the edges of the two sides of the front surface of the substrate, the waterproof groove is disposed on the edges around the front surface of the substrate, and the stress release groove structure is disposed on the side surface of the substrate, thereby effectively improving the bonding strength between the plastic encapsulation body and the lead frame and the substrate, reducing a stress change, enhancing the moisture-proof performance of the light-emitting module and improving the reliability; the limit angles are disposed for limiting and fixing the substrate, and accurate positioning is performed in combination with the positioning ink, thereby preventing the substrate from deviation. The overall structure is conducive to the development towards the integrated packaging.

It will be understood that all or part of the steps in the various methods described in the above-mentioned embodiments may be implemented by related hardware instructed by programs, and these programs may be stored in a computer-readable storage medium which may include a read-only memory (ROM), a random-access memory (RAM), a magnetic disk, an optical disk or the like.

What is claimed is:

1. A light-emitting module, comprising a lead frame, a substrate, a light-emitting element, a plastic encapsulation body, a driver integrated circuit (IC) chip and a plurality of passive devices, wherein
the substrate is disposed on the lead frame, and the light-emitting element, the driver IC chip and the plurality of passive devices are disposed on the substrate;
the substrate is a double-sided metal-plated insulated substrate;
the plastic encapsulation body at least covers part of the lead frame, and a light condensation cavity is disposed in the plastic encapsulation body, is located above the light-emitting element 41 and covers the light-emitting element; and
a plurality of circuit wires are further etched on the substrate, and the light-emitting element, the driver IC chip and the plurality of passive devices are correspondingly connected based on the circuit wires.

2. The light-emitting module according to claim 1, wherein the substrate is a double-sided copper-clad ceramic substrate; and
a nickel-plated gold layer is further disposed on the substrate.

3. The light-emitting module according to claim 1, wherein a plurality of grooves are disposed on the lead frame, and the substrate is placed on the lead frame where the plurality of grooves are disposed; and
the plurality of grooves are transverse stripe grooves, longitudinal stripe grooves or oblique stripe grooves and are parallel to each other, and a number of the plurality of grooves is 2 or more.

4. The light-emitting module according to claim 1, wherein an optical light condensation component is disposed above the light condensation cavity.

5. The light-emitting module according to claim 1, wherein a fixing protection structure is disposed on at least one side surface of the light condensation cavity.

6. The light-emitting module according to claim 1, wherein the light condensation cavity comprises a first circular truncated cone cavity and a second circular truncated cone cavity, wherein the first circular truncated cone cavity is disposed above the second circular truncated cone cavity.

7. The light-emitting module according to claim 6, wherein a diameter of an upper bottom surface of the first circular truncated cone cavity is greater than a diameter of a lower bottom surface of the first circular truncated cone cavity; and
a diameter of an upper bottom surface of the second circular truncated cone cavity is greater than a diameter of a lower bottom surface of the second circular truncated cone cavity.

8. The light-emitting module according to claim 6, wherein a dam is disposed in the second circular truncated cone cavity, is disposed in an inner wall of the second circular truncated cone cavity and is located around the light-emitting element on the substrate.

9. The light-emitting module according to claim 6, wherein a cone angle of a circular truncated cone of the first circular truncated cone cavity is α, and a value range of α is 4° to 8°; and
a cone angle of a circular truncated cone of the second circular truncated cone cavity is β, and a value range of β is 14° to 22°.

10. The light-emitting module according to claim 1, wherein the lead frame further comprises a plurality of weld pins, wherein the plurality of weld pins are in-line weld pins or surface mount weld pins; and
the light-emitting module further comprises a plurality of bonding wires, wherein the substrate is correspondingly connected to the plurality of weld pins based on the plurality of bonding wires.

11. The light-emitting module according to claim 10, wherein a solder resist ink is disposed among pins of the light-emitting element, the driver IC chip and the plurality of passive devices and the plurality of bonding wires.

12. The light-emitting module according to claim 11, wherein a thickness of the solder resist ink ranges from 30 um to 40 um and a width of the solder resist ink ranges from 80 um to 120 um.

13. The light-emitting module according to claim 1, wherein at least one of the following configurations is satisfied: a plurality of stress release holes are disposed on two edges of a front surface of the substrate;
a waterproof groove is disposed on four edges of a front surface of the substrate; or
a stress release groove structure is disposed on a side surface of the substrate.

14. The light-emitting module according to claim 1, wherein a plurality of limit angles are further disposed on the lead frame and comprise at least two limit angles distributed at diagonal positions in four corners of the lead frame.

15. The light-emitting module according to claim 14, wherein any one of the plurality of limit angles comprises a transverse limit edge and a longitudinal limit edge, wherein a transverse limit edge and a longitudinal limit edge of a same limit angle in the plurality of limit angles are disposed crosswise.

16. The light-emitting module according to claim 15, wherein any transverse limit edge comprises a first limit structure and a second limit structure, wherein the first limit structure and the second limit structure are mountain-shaped; and
any longitudinal limit edge comprises a third limit structure and a fourth limit structure, wherein the third limit structure and the fourth limit structure are mountain-shaped.

17. The light-emitting module according to claim 16, wherein an included angle between the first limit structure and the second limit structure of any transverse limit edge is 50° to 70°, and an included angle between the third limit structure and the fourth limit structure of any longitudinal limit edge is 50° to 70°.

18. The light-emitting module according to claim 16, wherein any transverse limit edge has a same structure, and any longitudinal limit edge has a same structure.

19. The light-emitting module according to claim 16, wherein the first limit structure of any transverse limit edge has a height ranging from 0.02 mm to 0.03 mm, and the second limit structure of any transverse limit edge has a height ranging from 0.05 mm to 0.1 mm; and
the third limit structure of any longitudinal limit edge has a height ranging from 0.02 mm to 0.03 mm, and the fourth limit structure of any longitudinal limit edge has a height ranging from 0.05 mm to 0.1 mm.

20. The light-emitting module according to claim 1, wherein a material of the lead frame is a metal material; and,
a positioning ink is further disposed on the substrate.
